(19) United States
(12) Patent Application Publication
(10) Pub. No.: US 2008/0236667 A1
(43) Pub. Date: Oct. 2, 2008

(54) Photovoltaic cell, enhanced spectrum conversion film, preparation of enhanced spectrum conversion film

(75) Inventors: Soshchin Naum, Changhua City (TW); Wei-Hung Lo, Taipei (TW); Chi-Ruei Tsai, Wunshan District (TW); Chien-Yi Chen, Niaosong Township (TW)

Correspondence Address: TROXELL LAW OFFICE PLLC, 5205 LEESBURG PIKE, SUITE 1404, FALLS CHURCH, VA, 22041, US

(73) Assignee: Wei-Hung Lo

(21) Appl. No.: 11/980,728

(22) Filed: Oct. 31, 2007

(30) Foreign Application Priority Data
Mar. 9, 2007 (TW) 096108130

(51) Int. Cl. H01L 31/0264

(52) U.S. Cl. 136/261; 257/E31.004

(57) ABSTRACT

Photovoltaic cell and enhanced spectrum conversion film enhanced spectrum conversion film that moves light emitting spectrum between solar radiation peak wavelength (λ=470 nm) and maximum sensitive wavelength of monocrystal silicon chip to light (λ=860˜880 nm) with battery percent of effectiveness 14˜16%. The enhanced spectrum conversion film transfers radiation of solar short-wavelength visible light to yellow and yellow orange color. The enhanced spectrum conversion film is an oxygen-contained polymer filled with fluorescent powder particles that are prepared from an oxide compound of group II or III and using a starter that has electron transition in d-layer and f-layer. The fluorescent powder is composed of aluminate solid solution of barium and yttrium, having the chemical formula Ba_{α}(Y, Gd)_{3β}Al_{2α+5β}O_{4α+12β} and the system of crystal lattice varied subject to the ratio between barium and yttrium. The percent of effectiveness of the photovoltaic cell reaches 18˜18.7% on full run.

### BACKGROUND OF THE INVENTION

1. Field of the Invention

The present invention relates to the photovoltaic cell and more particularly, to a photovoltaic cell with an enhanced spectrum conversion film that transfers the radiation of solar short-wavelength visible light to yellow and yellow orange color wavelength so that the percent of effectiveness of the photovoltaic cell can reach 18˜18.7% on full run.

2. Description of the Related Art

The simplest architecture of a photovoltaic cell is the use of a monocrystal silicon chip to convert solar energy into electrical energy. A monocrystal silicon chip for this purpose generally is a p-type conductive semiconductor monolithic chip prepared from a monocrystal silicon chip added with boron. Normally, dispersing gas-phase stibium compound on a p-type silicon chip causes p-n transformation on the surface of the silicon chip. A conductive type silicon chip changes electron-hole conduction to electron conduction, i.e., it exhibits n-type conduction. The concentration of the n-type film coated on the surface of the silicon chip is 0.5˜3 μm. The film is normally kept in contact with a metal electrode (electrode of gold or its alloy). The back side of the silicon chip is fully covered with a metal electrode or electrode of silver film.

The physical principle of the working of a photovoltaic cell is outlined hereinafter. When the photovoltaic cell is excited by the radiation of sunlight or artificial light, the photons absorbed by the silicon material produce unbalanced electron-hole pairs. At this time, electrons in p-layer near p-n transition move toward the boundary and are attracted to n-type zone by existing electric field. On the other hand, the electron-hole carriers (p-type carriers) in the n-layer on the surface of the silicon chip are partially transferred to the inside of the silicon chip, i.e., to the p-type zone. This dispersion results in that the n-type layer gets extra negative charges, and the p-type layer gets extra positive charges, and the contact potential difference between p-layer and n-layer of the semiconductor silicon chip is reduced. At this time, a voltage is produced in the external circuit. The negative terminal of the semiconductor is the n-layer, and its positive terminal is the p-layer.

The photoelectric effect of a silicon chip under the radiation of light can be described by volt-ampere characteristic equation:

U=(KT/q)*ln [(Iₚₕ−I)/Iₛ+I_{z}]

in which, Iₛ: supply current; Iₚₕ: optical current.

The maximum power obtainable from the surface of the semiconductor silicon chip per square centimeter is Iₚₕ*U=X*I_{K3}*I_{XX}, in which X: coefficient of volt-ampere proportion; I_{K3}: short-circuit current; I_{XX}: idle load voltage. The effective working coefficient of the aforesaid simplest photovoltaic cell structure is 15˜16%. A photovoltaic cell of one single semiconductor chip can obtain power as high as 40 W.

The aforesaid photovoltaic cell structure has the major drawback of uneven concentration of the p-layer and n-layer on the surface of the semiconductor silicon chip. Further, the maximum value of p-n spectrum of the silicon at the active state cannot match the spectrum of the radiation of sunlight.

The aforesaid deviation is explained hereinafter. FIG. 1 is a schematic drawing showing the basic architecture of a conventional photovoltaic cell, in which reference number 1 indicates p-type monocrystal silicon chip; 2 indicates n-type conduction layer; 3 indicates electrode system; 4 indicates outer anti-reflection film coating. Normally, a anti-dust shell is provided to surround the silicon chip of the photovoltaic cell. The anti-dust shell is prepared from ethyl acetate or polycarbonate compound.

From the spectrum of solar radiation measured at mid-latitude (for example, north latitude 48°) where the sun and the horizontal line show an angle of 45°, we can see that the maximum energy of solar radiation is at 290˜1060 nm (it is to be understood that when a photovoltaic cell is working in near-earth space environment, the full-spectrum diagram shows that the shortwave radiation and wavelength of UV and VUV wavebands are greater than the radiation of 1065 nm ultrared midwave; when a photovoltaic cell is working on the surface of the earth, the radiation of shortwave will be absorbed by oxygen in the atmosphere, and the radiation of UV midwave will be strongly absorbed in vapor).

Further, the spectrum of solar radiation shows uneven distribution of energy. The maximum energy value appears at blue band λ=470 nm. The maximum value of the energy of the waveband of visible light 500˜600 nm of solar radiation is reduced by 20%, and the radiation value corresponding to λ=720 nm is reduced to one half. The radiation value corresponding to λ=1000 nm=1μ is simply ⅕ of the maximum value. FIG. 2 is a sensitivity standard spectrum curve obtained from a conventional photovoltaic cell corresponding to different wavebands of solar radiation. When compared the spectra of solar radiation to the data shown in FIG. 2, it is seen that the maximum value of the monocrystal silicon chip at λ=400˜470 nm does not surpass 20% of the maximum sensitivity. When at λ=440˜880 nm, the sensitivity curve of the monocrystal silicon chip rises sharply, i.e., the monocrystal silicon chip photovoltaic cell is less sensitive to visible light and near-infrared light. However, the maximum sensitivity value of an IM125 photovoltaic cell appears at 950˜980 nm. The result that the maximum sensitivity of a monosilicon photovoltaic cell appears at the aforesaid narrowband is determined subject to the energy band architecture of the monocrystal silicon chip, its width is Eg=1.21 ev, and the corresponding wavelength is λ=950 nm.

Through the aforesaid comparison between the solar radiation and the spectral sensitivity of the monocrystal silicon chip, it obtains the conclusions: 1. The gap between the wavelength of the peak value of solar radiation and the wavelength corresponding to the photovoltaic cell maximum sensitivity is Δλ=500 nm, and the corresponding energy gap is ΔE=0.42 ev. 2. The sensitivity of the monocrystal silicon chip corresponding to the energy band 380˜550 nm of solar radiation is low; 3. the wavelength of the peak value of solar radiation is about twice the wavelength of the photon of the radiation of the monocrystal silicon chip at the highest sensitivity.

These important physical conclusions determine the major drawbacks of conventional monosilicon photovoltaic cells as follows:

1. The effective coefficient of these conventional photovoltaic cells is low, and the theoretical maximum value is determined subject to the integral relation between the spectral sensitivity of the monocrystal silicon chip and solar radiation, not over 28˜30%.

2. The peak value of midwave of solar radiation is at λ=470˜620 nm, which is weak in exciting a monosilicon photovoltaic cell. The extra energy of the photons of solar radiation after having been absorbed by the solar cell material will cause phonon radiation, producing hν=500 cm⁻¹(˜0.1 ev) phonons to increase the temperature of the solar cell material. At the same time, the wavelength corresponding to the monosilicon photovoltaic cell moves toward the waveband 980˜1020 nm. At this waveband, vapor shows significant influence to transmission of solar radiation through the atmosphere.

3. The energy of shortwave λ=2.5˜3 ev of solar radiation will cause solar cell material to produce irreversible defects such as to produce a vacancy at wave node and to form atoms between wave nodes, lowering the effect of the stopper layer of the photovoltaic cell.

These deviations cause conventional photovoltaic cells unable to reach the aforesaid 15˜16% effective working coefficient. Photovoltaic cell researchers and manufacturers keep studying for long to fin ways that eliminate the aforesaid defects and limitations. In the symposium paper “Thin-film Photovoltaic Cell” (published in 1985 by World Publishing Company, pages 378˜379), Chopr disclosed a solution to solve the aforesaid problems, which is used in the present invention as a prototype. FIG. 3 is one drawing of the aforesaid symposium paper. The physical meaning of this solution is the coating of a single layer of monocrystal red stone on the surface of the photovoltaic cell to enhance absorption of 2.3˜3.2 ev solar radiation that excites Cr⁺³ to cause d-d transition, producing narrow band illumination. The wavelength corresponding to the radiation peak value of the internal Cr⁺³ of red stone is λ=695 nm. Therefore, the primary radiation of sunlight is shifted toward long waveband, and the radiation of short wave band is completely shifted to radiation zone λ=700 nm.

In the coordinate chart of “photon energy-optical absorption coefficient” as shown in FIG. 3, curve 2 shows the optical absorption efficient of excited Cr⁺³, and curve 1 shows the illumination status of the monocrystal red stone when excited by light. FIG. 3 also indicates the carrier aggregation coefficient of the monosilicon photovoltaic cell after covered with layer of red stone on its surface (curve 3). This coefficient changes subject to existence of red stone layer. As indicated, the carrier aggregation coefficient of the short wave band radiation zone that is directly excited by solar radiation is 10˜20% higher than the light emitting device based on red stone frequency converter. The author of the aforesaid symposium paper gets the conclusion that the effectiveness of a monosilicon photovoltaic cell based on a red stone frequency converter still can be improved by 0.5˜2%. This is a substantial progress in photovoltaic cell technical field. However, there are still many other problems such as: 1. The spectrum of red stone Al₂O₃.Cr that is excited to emit light does not match with the sensitivity curve of the monosilicon photovoltaic cell completely; 2. Because of the use of monocrystal red stone, the cost of the monosilicon photovoltaic cell is high.

### SUMMARY OF THE INVENTION

The present invention has been accomplished under the circumstances in view. It is the main object of the present invention to provide a photovoltaic cell and enhanced spectrum conversion film, which adopt a broadband spectrum converter that enhances absorption of the radiation of visible light by about 80%.

It is another object of the present invention to provide a photovoltaic cell and enhanced spectrum conversion film of which the radiated spectrum of the enhanced spectrum conversion film is not within the narrowband but covers the energy-concentrated waveband λ=530˜610 nm.

It is still another object of the present invention to provide a photovoltaic cell and enhanced spectrum conversion film of which the enhanced spectrum conversion film is made in the form of a thin-film polymer having filled therein hyperdispersant inorganic fluorescent powder particles, and kept in direct contact with the surface of a p-type monocrystal silicon chip to convert at least 16% of light energy into electrical energy.

To achieve these and other objects of the present invention, the photovoltaic cell comprises a silicon chip set adapted to carry an enhanced spectrum conversion film, and an enhanced spectrum conversion film made in the form of a thin-film polymer. The thin-film polymer comprises an inorganic fluorescent powder disposed in contact with the surface of the silicon chip set to enhance absorption of a first specific waveband of natural light and to radiate a second specific waveband. Further, the wavelength of the first specific waveband is 300˜580 nm, and the wavelength of the second specific waveband is 530˜610 nm.

To achieve the aforesaid and other objects of the present invention, the enhanced spectrum conversion film is provided for use in a photovoltaic cell, and made in the form of a thin-film polymer. The thin-film polymer comprises an inorganic fluorescent powder disposed in contact with the surface of the silicon chip set to enhance absorption of a first specific waveband of natural light and to radiate the absorbed first specific band of natural light to a second specific waveband. Further, the wavelength of the first specific waveband is 300˜580 nm, and the wavelength of the second specific waveband is 530˜610 nm.

### BRIEF DESCRIPTION OF THE DRAWINGS

FIG. 1 is a schematic drawing showing the basic architecture of a conventional photovoltaic cell.

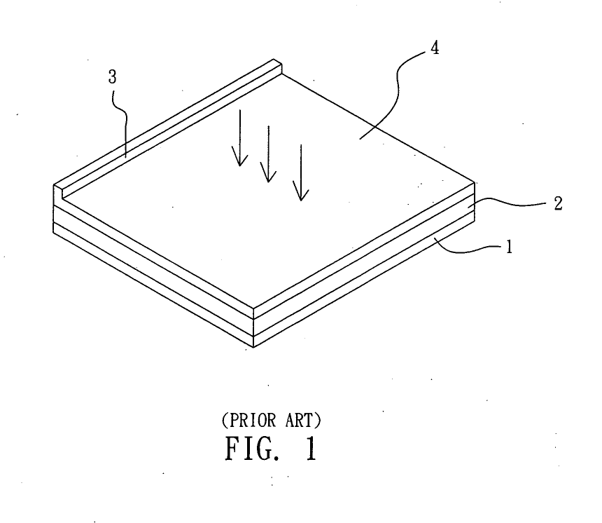

FIG. 2 is a sensitivity standard spectrum curve obtained from a conventional photovoltaic cell corresponding to different wavebands of solar radiation.

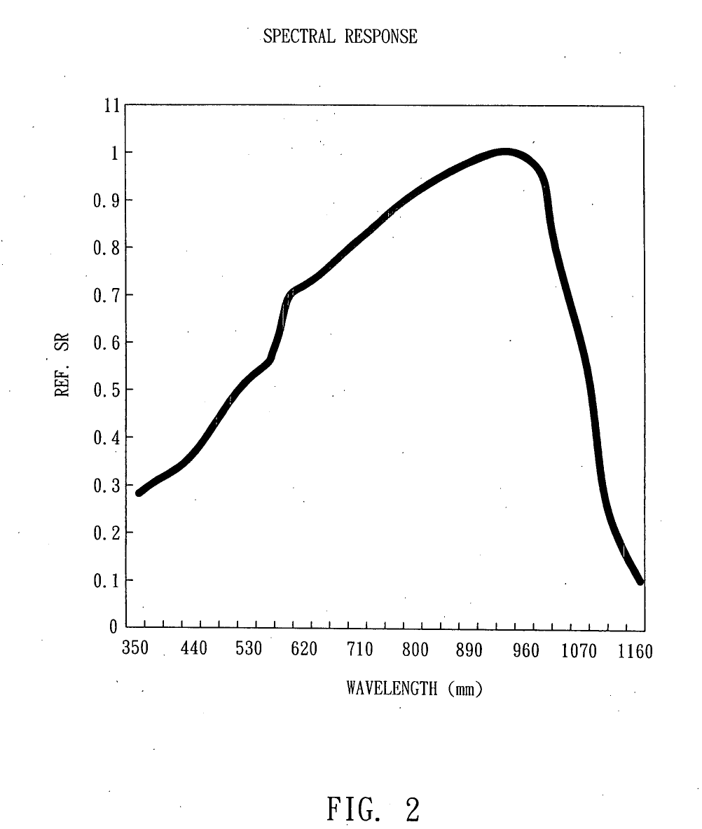

FIG. 3 is a schematic drawing showing solar radiation absorption enhancement at 2.3˜3.2 ev after the photovoltaic cell covered with a layer of monocrystal red stone.

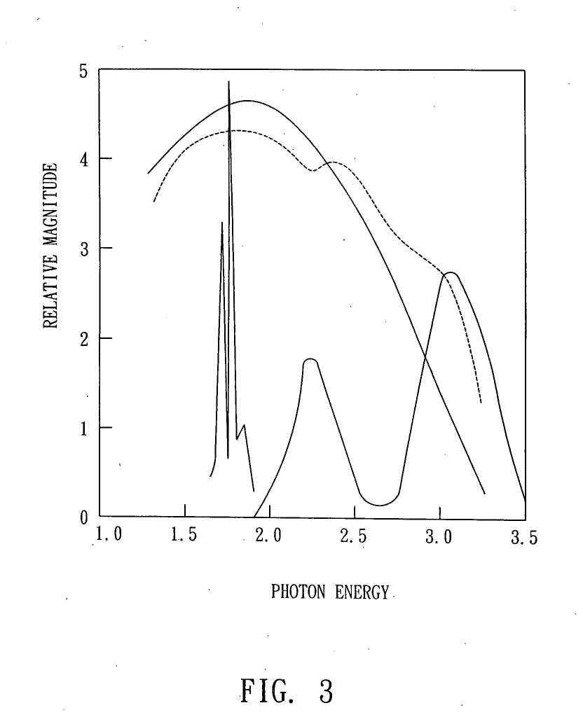

FIG. 4 is a schematic drawing showing the structure of a photovoltaic cell made according to the present invention.

FIG. 5 is a schematic drawing showing the preparation of a fluorescent powder in accordance with one preferred embodiment of the present invention.

### DETAILED DESCRIPTION OF THE PREFERRED EMBODIMENT

Till the present time, there is no any person who reported a data of same level with respect to the maximum effectiveness of photovoltaic cell. A photovoltaic cell that is constructed by means of a single crystal silicon chip and an enhanced spectrum conversion film can achieve this technical level just because the enhanced spectrum conversion film in the battery is a polymeric compound based on polycarbonate and/or polysiloxane and/or sodium poly acrylate and filled with fluorescent powder particles that are prepared from an oxide compound of group II, III, or IV The particles have a garnet crystal architecture. Further, the filling amount of the fluorescent powder in the polymer is within 0.1˜50%.

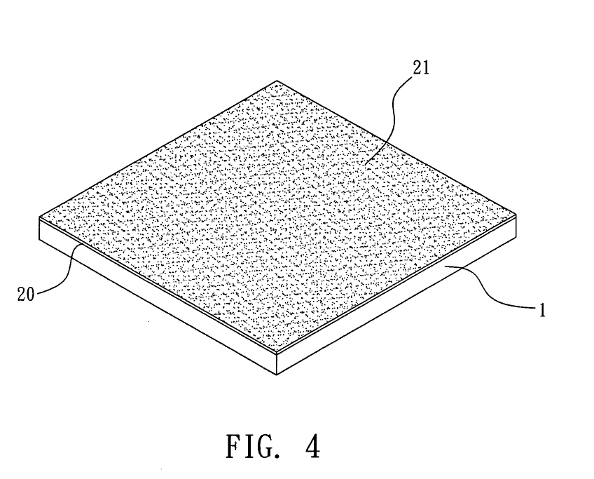

FIG. 4 is a schematic drawing showing the structure of a photovoltaic cell in accordance with the present invention. As illustrated, the photovoltaic cell is comprised of a silicon chip 10, and an enhanced spectrum conversion film 20.

The silicon chip 10 can be a p-type single crystal silicon, p-type poly-silicon, n-type single crystal silicon, or n-type poly-silicon. According to this embodiment, the silicon chip is a p-type monocrystal silicon. According to the present invention, total 16˜20 pieces of silicon chips are used to construct a parallel circuit having a plain surface not greater than 120 mm and a total resistance smaller than 100Ω.

The enhanced spectrum conversion film 20 is a thin polymer film containing an inorganic fluorescent powder 21, for example, hyperdispersant inorganic fluorescent powder particles, and disposed in contact with the outer layer of the single crystal silicon chip 10 to enhance absorption of a first specific waveband, for example, 300˜580 nm natural light, and to radiate it to a second specific waveband, for example, 530˜610 nm. The enhanced spectrum conversion film 20 is an organic polymer of average degree of polymerization m=100˜500, molecular weight 10000˜20000 standard units. Further, the enhanced spectrum conversion film 20 comprises epoxy to enhance its power in spectrum conversion.

The substrate of the inorganic fluorescent powder 21 is composed of aluminate solid solution of barium and yttrium. The chemical formula of the inorganic fluorescent powder 21 can be, for example, Ba_{α}(Y, Gd)_{3β}Al_{2α+5β}O_{4α+12 β}, in which α≦1 or α≧1; β≦1 or, β≧1. The system of the crystal lattice varies subject to the ratio between barium and yttrium. When α≦0.1, the crystal lattice is a cubic crystal system; when α=1, β≦0.1, the crystal lattice is a hexagonal crystal system; when α=1, β=1.0, the crystal lattice is a monoclinic crystal system. When the aforesaid inorganic fluorescent powder is added with f element and d element: Ce, Pr, Eu, Dy, Tb, Sm, Mn, Ti, or Fe, the oxidized extent will be within +2˜+4. When the substrate polymer is excited by short band λ≧470 nm, the aforesaid ions will radiate orange green light of wavelength λ=530˜610 nm, and the radiation will be absorbed by the P layer of the single crystal silicon of total concentration 100˜300 μm.

The enhanced spectrum conversion film 20 is an oxygen-contained polymer based on polycarbonate and/or polysiloxane and/or sodium poly acrylate. The polymer has filled therein fluorescent powder particles prepared from an oxide selected from group II, III, or IV of periodic table of elements that has a garnet crystal architecture. The content of the fluorescent powder grin in the polymer is 0.1˜50%. Further, the enhanced spectrum conversion film 20 shows the color of yellow orange, and its light absorption at 300˜520 nm is greater than 60%. Further, the quantum radiance of the enhanced spectrum conversion film 20 varies within 75˜96%, and is relatively increased subject to optimization of concentration in the film within 0.1˜0.5 mm. The reflective rate of the enhanced spectrum conversion film 20 relative to the total natural light received by the battery is 4˜6%.

The enhanced spectrum conversion film 20 is composed of a polycarbonate film of molecular weight m=12000 standard carbon units.

The physical essence of the photovoltaic cell of the present invention is described hereinafter. At first, select the material of polycarbonate and/or polysiloxane and/or sodium poly acrylate for the enhanced spectrum conversion film 20 for the advantage of high transmissive at broadband λ=400˜1200 nm. Further, the aforesaid polymer has a relatively higher damage threshold against solar short-wave radiation.

The enhanced spectrum conversion film 20 further comprises the inorganic fluorescent powder 21 prepared from an oxide of group II or III. The particle size of the inorganic fluorescent powder 21 is smaller than the wavelength of solar radiation that induces the inorganic fluorescent powder 21 to emit light, thereby changing the light scattering behavior rule of the inorganic fluorescent powder 21 (under this circumstances, the Relei's law of light scattering is subject to the behavior rule established by Mi). To overlap light emission spectra on the primary radiation of sunlight, the content of the inorganic fluorescent powder 21 in the enhanced spectrum conversion film 20 should be within about 0.1˜50%. The preparation of the enhanced spectrum conversion film 20 is to solve polymer in an organic solvent such as methane dichloride, ethylene trichloride, and then to cast the solution into the desired finished product.

Because the enhanced spectrum conversion film 20 eliminates or has only low light scattering, the light transmission rate of the enhanced spectrum conversion film 20 at concentration 80˜100 μm can reach 85% (during direct radiation), and the transmissive light will show the color of yellow orange.

The substrate of the inorganic fluorescent powder 21 is composed of aluminate solid solution of barium and yttrium. In one example of the present invention, the chemical formula of the inorganic fluorescent powder 21 is Ba_{α}(Y, Gd)_{3β}Al_{2α+5β}O_{4α+12β} that can be excited by Ce⁺³ or Pr⁺³, or by both Ce⁺³ and Pr⁺³. These ions produce radiation subject to its internal d-f transition.

According to tests, the concentration of the fluorescent powder of garnet architecture at 1˜3% provides the maximum brightness when excited by Ce⁺³ and/or Pr⁺³. The content of garnet type homocrystal architecture is reasonably high when compared to the amount of d-f enabled element. Further, the aforesaid chemical formula provides a method to have the radiation of the inorganic fluorescent powder 21 toward the direction of long wave. The method is to substitute Gd ions for a part of Y ions. At this time, the radiation of Ce⁺³ or Pr⁺³ goes toward the direction of long wave corresponding to 530˜590 nm or 600˜625 nm. When substituting 1% Gd ions for 1% Y ions, peak wavelength moves 1 nm.

The physiochemical properties of the present invention are as follows:

At first, aluminate and yttrium aluminate of Group II elements have similar optical characteristics, like MeAl₂O₄ (When Me=Mg or Ca, it forms a compound of cubic crystal system like spinel) or Me₄Al₇O₁₅. When the compound is started by Ce⁺³, it has strong light emission characteristics and can be excited to emit light by light beam λ≦470 nm.

Experiments of the invention also discovered the light emission characteristics are enhanced when monoatuminate and polyaluminate of Group II elements form with Y₃Al₅O₁₂ garnet type yttrium aluminate or YAlO₃ type garnet type yttrium aluminate a solid solution. This solid solution contains an integral number of MeAl₂O₄ type monoaluminate. For example, a unit yttrium aluminum garnet may contain 1, 2, 3, or 4 units aluminate. However, it may obtain a non-integral number of monoaluminate solid solution. For example, the amount of MeAl₂O₄ can be 0.1, 0.25, 0.4, or 0.5. The solid solution formed of aluminate and yttrium aluminate of Group II elements contains a small amount of the later. Under this condition, when α=1, β≦0.1, the crystal structure of the solid solution is close to hexagonal crystal system; when α≦0.1, β=1, the crystal structure of the solid solution is close to the typical yttrium aluminate garnet cubic crystal system. At this time, the crystal lattice parameters is close to a=12.4 Å, greater than the crystal lattice parameters of standard Yttrium Aluminum garnet (YAG). However, in the crystal lattice having such parameter value, Ce⁺³ is more easily soluble (the solubility can be over 15%, the average solubility of Ce₂O₃ in standard Yttrium Aluminum garnet is below 3%).

Further, when α≦1, β≦1, the crystal lattice structure of the solid solution is bulky, belonging to monoclinic system (a, b, c, γ angle).

The solid solution that is formed of aluminate and yttrium aluminate of Group II elements can well dissolve bigger ions such as Ce⁺³. Similar to Ce⁺³, the light rare earth element Pr⁺³ is also easily soluble in this solid solution. Heavy rare earth elements such as Dy⁺³, Tb⁺³, Eu⁺³ and the element Sm⁺³ that is in the position between light rare earth elements and heavy rare earth elements are also soluble in the synthesized solid solution. At this time, Eu⁺² and Sm⁺² that have variable valence may exist in two different oxidation status: +2 valence state and +3 valence state, and Mn⁺² with Mn⁺⁴, Ti⁺³ with Ti⁺⁴, and Fe⁺² with Fe⁺³ may individually or simultaneously exist in the crystal lattice structure of the solid solution. At this time, all the aforesaid ions have a strong light emission characteristic (in which certain ions, such as Ti⁺³ regain this light emission characteristic). All the aforesaid highly luminant ions are excitable to emit light at the band near ultraviolet band (Dy⁺³, Tb⁺³, Mn⁺⁴, Ti⁺³) or visible light λ=440 nm blue band.

In the aforesaid new compound, many different starting agents are used for the following advantages: 1. The spectrum of the fluorescent powder covers a relatively wider waveband; 2. It allows to alter or modify the primary color of light by means of adding a trace amount of second or even third starting agent; 3. It allows to change the color of the fluorescent powder by means of selecting a different frequency of exciting light.

Any sampling of the toichiometric parameter α and β within the sampling range shows the aforesaid advantages. For 1 m Y₃Al₅O₁₂, the result is most excellent when α=0.25 and α=0.5. At this time, the crystal lattice of the fluorescent power shows a cubic system. Compound BaAl₂O₄ and Y₃Al₅O₁₂ are respectively started by Eu⁺² and/or Ce⁺³, and solved to form a fluorescent powder.

When toichiometric parameter α=1 and β≦0.1, fluorescent powder of chemical formula BaY_{0.3}Al_{2.5}O_{5.2} is formed, which is started by Eu⁺² and/or Sm⁺² to emit light within the blue-green narrowband, spectrum line halfwidth≦λ_{0.5}=60˜70 nm. At this time, the fluorescent powder substrate shows the structure of an orthorhombic system. When excited by λ=460 nm blue light, it emits blue green color of light of color coordinate x=0.17˜0.22, y=0.45˜0.55.

Except the traditional starting agent Ce⁺³, solve Ti⁺³ and Fe⁺³ in the fluorescent power substrate can increase the peak value of the radiation by 125˜130 nm, and the color coordinate at this time has orange-red characteristic: x≦0.40, y≦0.45.

When add BaAl₂O₄ of toichiometric parameter α≧1, the crystal of the solid solution shows the structure of an orthorhombic system. At this time, Gd⁺³ is used to substitute for a part of Y⁺³. At this time, the peak value of the radiation of the fluorescent powder will move toward the longwave, from the band of λ=558 nm to the band of λ≦570 nm. The sum of color coordinates is Σ(x+y)≧0.80. The advantage of this fluoresdcent powder sample is its emission of high temperature red color of light.

Variation of toichiometric parameter α, β within the range of α/β≧2 will cause the color of the fluorescent powder to be darkened. When α=1 and β=0.1, the fluorescent powder shows a light yellow color close to grass-yellow, and it is gradually changed to gold color following increase of the sampling value of α. The minimum radiation absorption value appears at the band of λ=440˜480 nm. The maximum reflection value appears at the band of λ≧560 nm, and reaches R=90˜95%.

As stated above, Sr⁺² or Ca⁺² may be used to substitute for a part of anion sub-latice Ba⁺². At this time, fluorescent powder substrate can be started by Eu⁺², Sm⁺² or Mn⁺² to radiate within the narrowband 505˜585 nm, Δλ=100˜110 nm.

The invention has also studied the motion characteristics of the fluorescent powder. When toichiometric parameter α=1 and β≦0.5, the fluorescent luminance tₑ100˜50 ns; when β/α≧4, the fluorescent luminance is reduced to t=40˜50 ns.

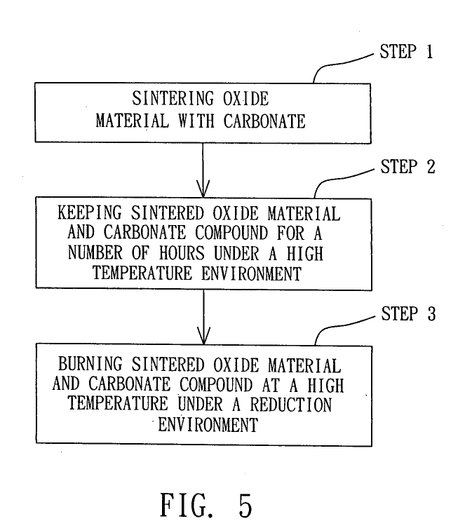

The fluorescent powder may be synthesized in many ways. FIG. 5 is a flow chart showing the preparation of the fluorescent powder in accordance with one preferred embodiment of the present invention. The preparation includes the steps of sintering a selected oxide material with carbonate (Step 1), keeping it for a number of hours under a high temperature environment (Step 2), and burning at a high temperature under a reduction environment (Step 3).

The composition of the fluorescent powder made according to the present invention is as shown in the following Table 1

TABLE 1
Characteristics of fluorescent powder
for Enhanced Spectrum Conversion Film

| | | Peak | Peak | |
|---|---|---|---|---|
| | | wave- | half- | Photo |
| | | length, | width, | radiance, |
| No. | Composition | nm | nm | % |
| 1 | Ba_{0.25}Y₃Al_{5.5}O₁₃: Ce | 540 | 125 | 80 |
| 2 | Ba_{0.25}Y₃Al_{5.5}O₁₃: Ce, Pr | 540, 610 | 125, 10 | 75 |
| 3 | Ba_{0.25}Y_{1.5}Gd_{1.5}Al_{5.5}O₁₃: | 560 | 127 | 75 |
| | Ce | | | |
| 4 | Ba_{0.25}Y_{1.5}Gd_{1.5}Al_{5.5}O₁₃: | 560, 615 | 127, 10 | 72 |
| | Ce, Pr | | | |
| 5 | Ba_{0.5}Y₃Al₆O₁₄: Ce | 545 | 125 | 85 |
| 6 | Ba_{0.5}Y₃Al₆O₁₄: Ce, Pr | 545, 610 | 125, 10 | 78 |
| 7 | Ba_{0.5}Y_{1.5}Gd_{1.5}Al₆O₁₄: Ce | 563 | 127 | 78 |
| 8 | Ba_{0.5}Y_{1.5}Gd_{1.5}Al₆O₁₄: | 563, 615 | 127, 10 | 84 |
| | Ce, Pr | | | |

The absorption spectrum shows that all the aforesaid materials strongly absorb the radiation of the visible light band because the mixed powder shows a yellow color or yellow orange color. Because the fluorescent powder particles have such a bright color, the fluorescent powder can be used to reduce the reflection coefficient of the surface of a photovoltaic cell, thereby lowering the requirement for the external architecture of the photovoltaic cell. According to the modern manufacturing technology, the silicon chip is covered with a layer of Si₃N₄ coating to make the surface luminous. However, the application of this operation technique is difficult and expensive, greatly increasing the commercial cost of the photovoltaic cell.

The enhanced spectrum conversion film 20 can be prepared in one of the following two ways. 1. Cast polymer suspension on the surface of the monocrystal silicon chip 10. The enhanced spectrum conversion film 20 made according to this method has a geometric size approximately equal to the silicon chip 10. The concentration of the fluorescent powder particles 21 in the polymer suspension is 0.5˜50%. When the concentration of the fluorescent powder particles 21 is lower, the polymeric film thickness must be relatively increased. When the concentration of the fluorescent powder particles 21 is higher, the polymeric film thickness can be reduced to about 20˜60 μm. Under this condition, the enhanced spectrum conversion film 20 can absorb 60˜90% of the light radiated on its surface, assuring a relatively higher emission efficiency and photon radiance. The photovoltaic cell has this benefit just because the surface of the enhanced spectrum conversion film 20 shows a yellow orange color of which the absorption rate at 300˜520 mm is over 60%. Further, the photon radiance is 75˜96%, and will be relatively increased following optimalization of the concentration of the polymeric film concentration within 0.1˜0.5 mm. The reflection rate of the enhanced spectrum conversion film 20 against the light radiated thereon is 4˜6%.

Further, the enhanced spectrum conversion film 20 has the following features. The average polymerization degree of the organic polymer of the enhanced spectrum conversion film 20 is about 100˜500, assuring the molecular weight to be close to 10000˜20000 standard carbon units. When the polymerization degree and the molecular weight are low, the polymerized film will be excessively hard, resulting in a low plasticity. On the other hand, increasing the polymerization degree will lower the light transmission of the polymer, in sequence, lowering the performance of the photovoltaic cell.

Further, the study of the present invention also discovered the best way of making the enhanced spectrum conversion film 20 by: solving polycarbonate in CH₂Cl₂ to form a 20% solution and then cast-molding the solution. At this time, the molecular weight of polycarbonate is 12000 standard carbon units. The chemical composition is Ba_{α}(Y,Gd)_{3β}Al_{2α+5β}O_{4α+12β}, and the optimal stuffing concentration of the average diameter 0.6 μm fluorescent powder in the polymer is 20%. The concentration of the polymerized layer of the enhanced spectrum conversion film cast-molded on the surface of the silicon chip is 60±5 μm. Therefore, a number of enhanced spectrum conversion film 20 covered silicon chips 10 are assembled to form a photovoltaic cell.

Except the aforesaid cast molding method, the enhanced spectrum conversion film 20 can be made from polyethylene by means of extrusion under a high temperature of 190° C. The technique of making a polyethylene film by means of extrusion has been described in the aforesaid patent specification. Therefore, no further detailed description in this regard is necessary. It is to be understood that the concentration of the fluorescent power in the film is 18%. The physical composition is: low concentration polyethylene 62%, EVA20%, fluorescent powder 18%, polyethylene film concentration 120±10 μm, having high homogeity and toughness. A specific bonding agent is applied to bond the fluorescent powder-contained polyethylene to the surface of the silicon chip.

The architecture of the photovoltaic cell is described hereinafter. Normally, a battery is formed of a set of silicon chips that are connected in paralle. The number of the silicon chips in a battery is determined subject to the geometric size of the monocrystal silicon chips 10. The following Table 2 lists the specification parameters of the monocrystal silicon chips 10. The area of the cross section of the pseudo-square (the four angles are defective) of the silicon rod is 125*125±0.5 mm. The silicon chips have a standard concentration 300±30 μm. Because this kind of silicon chip has a great mass (>25 g), the cost for the monocrystal silicon chips 10 required for making a photovoltaic cell is greatly increased. Therefore, during study of the present invention, relatively thinner silicon chips (concentration 1=240±0.5 μm). The use of this kind of silicon chip can reduce the cost by 20%, further, the resistance variation ran ge of this kind of silicon chip is the least (10%), facilitating assembly of battery. Normally, a photovoltaic cell of 0.25 m² is composed of 16 pieces of monocrystal silicon chips. A photovoltaic cell may be composed of 64 or 144 pieces of monocrystal silicon chips for use with a big scale instrument.

TABLE 2

| 1 | Growth method | Czochralskii | |
|---|---|---|---|
| 2 | Dopant | Boron | |
| 3 | Conductivity | P type | |
| 4 | Resistivity | 0.5~3.0 | ohm/cm |
| 5 | Diameter | 150 ± 0.5 | mm |
| 6 | Location | 100 ± 2 | degrees |
| 7 | Minority carrier life | >10 | ms |
| 8 | Stacking fault density | <10/cm² | |
| 9 | Oxygen content | 1*1018 | atom/cm³ |
| 10 | Carbon content | 5*1017 | atom/cm³ |
| 11 | Diagonal | 150 ± 1 | mm |
| 12 | Silicon chip plain size | 125.0*125.0 ± 0.5 | mm |
| 13 | W, X, Y, Z symmetry | 20.3~21.9 | mm |
| 14 | Square center | ≦0.3 | mm |
| 15 | Squareness & Parallelism | <0.5 | mm |
| 16 | Lateral edge positioning | (010), (001) | |
| 17 | Concentration | 300 ± 30 | μm |
| 18 | Concentration variation range | <30 | μm |
| 19 | Curvature | <50 | μm |
| 20 | Silicon surface positioning | 100 ± 3 | degrees |
| 21 | Surface visible layer | <20 | μm |
| 22 | Visible cut trace | <5 | μm |

| | | |
|---|---|---|
| 23 | Edge mass | Allow 2 notches of length <1 mm and |
| | | depth <0.3 mm. No crack. |

In addition to using monocrystal silicon chips 10 to assemble a photovoltaic cell, the invention also tried to assemble a photovoltaic cell with polysilicon chips. Polisilicon chip material was used to make a film, and the film thus obtained was arranged on a metal conductor holder base. According to the physical properties of polysilicon, the mobility of the carrier of a polysilicon chip is inferior to that the carrier of a monocrystal silicon. However, using polysilicon chips to assemble a photovoltaic cell can lower the battery cost.

The output characteristics of a photovoltaic cell using the aforesaid enhanced spectrum converting film 20 are described hereinafter. The photovoltaic cells used in the test were each formed of 128 pieces monocrystal silicon chips 10 respectively covered with an enhanced spectrum conversion film 20. All parameters of the monocrystal silicon chips 10 were within the standard variation range. The maximum percent of effectiveness of the batteries was 18.7%, and the output power at this time was 2.72 Watts. The maximum output voltage of the sample having the maximum percent of effectiveness was 0.620V, and the corresponding short-circuit current was 5.50 Amp. When compared to a regular most effective monocrystal silicon chip photovoltaic cell of the same series, a monocrystal silicon chip photovoltaic cell with enhanced spectrum conversion film 20 shows 1.2% higher in maximum percent of effectiveness, and the respective output voltage and short-circuit current are also relatively higher.

The test of the invention also shows that the percent of effectiveness of the poorest on among all monocrystal silicon chip photovoltaic cell samples with enhanced spectrum conversion film 20 in the test is 15% (the percent of effectiveness of a regular photovoltaic cell is about 13.5%), and the relative output voltage and short-circuit current are 0.600 Watt and 4.70 Amp respectively. When compared with conventional photovoltaic cells, this photovoltaic cell with enhanced spectrum conversion film 20 has many undisputable benefits.

The photovoltaic cell and enhanced spectrum conversion film of the present invention can improve monocrystal silicon chip's conversion efficiency at the higher energy band 380˜550 nm, thereby improving the conversion efficiency of the photovoltaic cell and showing the undisputable benefits.

As stated above, the photovoltaic cell and enhanced spectrum conversion film of the present invention comprise a polymeric film containing hyperdispersant inorganic fluorescent powder particles, and the polymeric film is kept in contact with the surface of a p-type monocrystal silicon chip. The technique has the prominent characteristic of converting at least 16% of natural light into electrical energy, thereby improving the drawbacks of conventional photovoltaic cells.

Although particular embodiments of the invention have been described in detail for purposes of illustration, various modifications and enhancements may be made without departing from the spirit and scope of the invention.

What is claimed is:

1. A photovoltaic cell comprising:
a silicon chip set adapted to carry an enhanced spectrum conversion film; and
an enhanced spectrum conversion film made in the form of a thin-film polymer, said thin-film polymer comprising an inorganic fluorescent powder disposed in contact with the surface of said silicon chip set to enhance absorption of a first specific waveband of natural light and to radiate the absorbed first specific band of natural light to a second specific waveband.

2. The photovoltaic cell as claimed in claim 1, wherein said inorganic fluorescent powder is comprised of hyperdispersant inorganic fluorescent powder particles.

3. The photovoltaic cell as claimed in claim 1, wherein the wavelength of said first specific waveband is 300˜580 nm, and the wavelength of said second specific waveband is 530˜610 nm.

4. The photovoltaic cell as claimed in claim 1, wherein said enhanced spectrum conversion film is an oxygen-contained polymer prepared from polycarbonate and/or polysiloxane and/or sodium poly acrylate and filled with fluorescent powder particles that are prepared from an oxide compound of group II, III, or IV, said fluorescent powder particles having a garnet crystal architecture, the content of said fluorescent powder particles in the polymer being within 0.1˜50%.

5. The photovoltaic cell as claimed in claim 2, wherein said inorganic fluorescent powder is composed of aluminate solid solution of barium and yttrium, having the chemical formula Ba_{α}(Y, Gd)_{3β}Al_{2α+5β}O_{4α+12β}, in which α≦1 or α≧1; β≦1 or β≧1.

6. The photovoltaic cell as claimed in claim 5, wherein when α≦1, β≦1, the crystal lattice structure of the solid solution is bulky, belonging to monoclinic system (a, b, c, γ angle).

7. The photovoltaic cell as claimed in claim 1, wherein said enhanced spectrum conversion film shows the color of yellow orange, and the light absorption of said enhanced spectrum conversion film at 300˜520 nm is greater than 60%.

8. The photovoltaic cell as claimed in claim 1, wherein the quantum radiance of said enhanced spectrum conversion film is within 75˜96%, and is relatively increased subject to optimization of concentration in the film within 0.1˜0.5 mm, and the reflective rate of said enhanced spectrum conversion film relative to the total natural light received by the photovoltaic cell is 4˜6%.

9. An enhanced spectrum conversion film made in the form of a thin-film polymer, said thin-film polymer comprising an inorganic fluorescent powder to be disposed in contact with the surface of a silicon chip set to enhance absorption of a first specific waveband of natural light and to radiate the absorbed first specific band of natural light to a second specific waveband.

10. The enhanced spectrum conversion film as claimed in claim 9, wherein said inorganic fluorescent powder is comprised of hyperdispersant inorganic fluorescent powder particles.

11. The enhanced spectrum conversion film as claimed in claim 9, wherein the wavelength of said first specific waveband is 300˜580 nm, and the wavelength of said second specific waveband is 530˜610 nm.

12. The enhanced spectrum conversion film as claimed in claim 9, which is an oxygen-contained polymer prepared from polycarbonate and/or polysiloxane and/or sodium poly acrylate and filled with fluorescent powder particles that are prepared from an oxide compound of group II, III, or IV, said fluorescent powder particles having a garnet crystal architecture, the content of said fluorescent powder particles in the polymer being within 0.1˜50%.

13. The enhanced spectrum conversion film as claimed in claim 9, wherein said inorganic fluorescent powder is composed of aluminate solid solution of barium and yttrium, having the chemical formula Ba_{α}(Y, Gd)_{3β}Al_{2α+5β}O_{4α+12β}, in which α≦1 or α≧1; β≦1 or β≧1.

14. The enhanced spectrum conversion film as claimed in claim 9, wherein when α≦1, β≦1, the crystal lattice structure of the solid solution is bulky, belonging to monoclinic system (a, b, c, γ angle).

15. A fluorescent powder preparation method comprising the steps of:
a) sintering a selected oxide material with carbonate;
b) keeping the sintered oxide and carbonate compound for a number of hours under a high temperature environment; and
c) burning the sintered oxide and carbonate compound at a high temperature under a reduction environment.

16. The fluorescent powder preparation method as claimed in claim 14, wherein the fluorescent powder thus obtained is an inorganic fluorescent powder composed of natrium aluminate solid solution of barium and yttrium, having the chemical formula Ba_{α}(Y,Gd)_{3β}Al_{2α+5β}O_{4α+12β}, in which α≦1 or α≧1; β≦1 or β≧1.

17. The fluorescent powder preparation method as claimed in claim 14, wherein when α≦1, β≦1, the crystal lattice structure of the solid solution is bulky, belonging to monoclinic system (a, b, c, γ angle).
